(19) United States
(12) Patent Application Publication
(10) Pub. No.: US 2006/0076600 A1
(43) Pub. Date: Apr. 13, 2006

(54) Semiconductor device and method for fabricating the same

(75) Inventors: Takashi Nakabayashi, Osaka (JP); Hideyuki Arai, Osaka (JP); Takashi Ohtsuka, Osaka (JP); Hisashi Yano, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/188,866

(22) Filed: Jul. 26, 2005

(30) Foreign Application Priority Data
Oct. 12, 2004 (JP) 2004-297464

(51) Int. Cl. H01L 29/94

(52) U.S. Cl. 257/298

(57) ABSTRACT

In a method for fabricating a semiconductor device according to the present invention, a groove is formed in a second interlayer insulating film, and then a storage electrode is formed which covers bottom and side surfaces of the groove. A capacitor insulating film is formed on the storage electrode, and a CVD method at a low temperature of 400° C. or lower and annealing with ammonia are repeated to form a TiOₓN_{y} film on the capacitor insulating film. A TiN film is formed on the TiOₓN_{y} film, and the TiN film is etched using the TiOₓN_{y} film as a stopper. The exposed TiOₓN_{y} film is then removed to form a plate electrode made of the TiOₓN_{y} film and the TiN film.

### CROSS-REFERENCE TO RELATED APPLICATIONS

This application claims priority under 35 U.S.C. § 119 on Patent Application No. 2004-297464 filed in Japan on Oct. 12, 2004, the entire contents of which are hereby incorporated by reference.

### BACKGROUND OF THE INVENTION

(a) Fields of the Invention

The present invention relates to semiconductor devices and methods for fabricating the device. In particular, the present invention relates to DRAM-embedded semiconductor devices (semiconductor devices with DRAMs embedded therein) which have CUB (Capacitor Under Bit-Line) structures, and methods for fabricating such a device.

(b) Description of Related Art

DRAM-embedded LSIs can have data buses of increased width between their memories and logics, and thereby excel in high speed processing of a large amount of data. The DRAM-embedded LSIs also have the property of reducing power consumption of systems therein without requiring any wiring such as a printed wiring board outside their packages and thereby highly excel as system LSIs.

Hereinafter, conventional problems of a method for fabricating a DRAM-embedded LSI will be described with reference to the accompanying drawings. FIGS. 4A, 4B, and 5 are sectional views showing conventional fabrication steps for a DRAM-embedded semiconductor device with a CUB structure in which a bit line is formed in a layer present on a storage capacitor. Note that the CUB structure as shown in FIGS. 4A, 4B, and 5 is disclosed in, for example, Prior Art Document 1 (VLSI Symp. Tech. Dig., p. 29, 2001 (M Takeuchi, et al.)).

In the conventional method for fabricating a DRAM-embedded semiconductor device, at the time of start of the step shown in FIG. 4A, part of a substrate 101 located in a DRAM region 140 is provided with a DRAM cell transistor 140a having doped source and drain layers 104 and a gate electrode 106, while part of the substrate 101 located in a logic region 141 is provided with a logic transistor 141a having doped source and drain layers 103 and a gate electrode 105. On top of the DRAM cell transistor 140a and the logic transistor 141a, a first interlayer insulating film 107 and a second interlayer insulating film 115 are formed. Part of the first interlayer insulating film 107 located in the logic region 141 is provided with a contact plug 108 in contact with a corresponding one of the doped source and drain layers 103, while part of the first interlayer insulating film 107 located in the DRAM region 140 is provided with a contact plug 109 in contact with a corresponding one of the doped source and drain layers 104. In the DRAM region 140, a groove 142 is provided which passes through the second interlayer insulating film 115 to reach the contact plug 109. Bottom and side surfaces of the groove 142 are covered with a storage electrode 116 (in a concave shape). Over the entire storage electrode 116 and the entire second interlayer insulating film 115, a plate electrode 125 of a TiN film is provided with a capacitor insulating film 117 interposed therebetween. In the step shown in FIG. 4A, a photoresist 121 is formed on the plate electrode 125 and patterning is performed to form a bit-line contact opening 122 in a portion of the plate electrode 125 located in the DRAM region 140, and a wide opening 123 in a portion of the TiN film located in the logic region 141.

Next, in the step shown in FIG. 4B, a third interlayer insulating film 127 is deposited on the second interlayer insulating film 115 and the plate electrode 125, and the deposited film is planarized by a CMP method. Thereafter, a photoresist 128 is formed on the third interlayer insulating film 127.

Subsequently, in the step shown in FIG. 5, etching is performed using a photoresist 128 (shown in FIG. 4B) as a mask to form, in the DRAM region 140, a groove 143 reaching the plate electrode 125 and a groove 144 made by removing a portion of the second interlayer insulating film 115 located on and in the bit-line contact opening 122. During this etching, simultaneously, in the logic region 141, a groove 145 is formed which passes through the third and second interlayer insulating films 127 and 115 to reach the contact plug 108. Thereafter, the grooves 143 to 145 are filled with metal to form a plate contact plug 130, a bit-line contact plug 131, and a logic contact plug 129. Metal wires 132 are then formed which come into contact with the respective contact plugs 129 to 131.

In the above-described conventional method for fabricating a DRAM-embedded semiconductor device, when the plate electrode 125 is etched in the step shown in FIG. 4A, a portion thereof to be the bit-line contact opening 122 having a smaller width than the wide opening 123 is etched at a decreased etching rate due to a microloading effect. Thus, a region of the plate electrode 125 to be the wide opening 123 is overetched, so that even part of the second interlayer insulating film 115 located below the plate electrode 125 is etched. Because of this overetching, between the DRAM region 140 and the logic region 141, a large level difference (step) is created which has a height of the height of the plate electrode 125 plus the depth of the overetched portion of the second interlayer insulating film 115. In such a state, when the third interlayer insulating film 127 is formed as shown in FIG. 4B, the level difference is reflected also on the upper surface of the third interlayer insulating film 127. Then, when the photoresist 128 is applied onto the third interlayer insulating film 127, the level difference formed on the top of the third interlayer insulating film 127 causes shift of focus, resulting in the occurrence of resolution failure. As a result, in forming the grooves 143 to 145 in the step shown in FIG. 5, control of the depths of the grooves becomes difficult, which causes a problem that opening failure arises in some of the grooves. To be more specific, the depth of the groove 144 is shallower than a desired value. Thus, the groove 144 does not reach a contact plug 110 and then the bit-line contact plug 131 does not come into contact with the contact plug 110.

FIGS. 6A and 6B are sectional views showing conventional fabrication steps of a DRAM-embedded semiconductor device with a COB (Capacitor Over Bit-Line) structure in which a storage capacitor is formed in a layer present on a bit line. Note that the fabrication method shown in FIGS. 6A and 6B is disclosed in, for example, Prior Art Document 2 (Japanese Unexamined Patent Publication No. 2003-31690).

In the conventional method for fabricating a DRAM-embedded semiconductor device, at the time of start of the step shown in FIG. 6A, bottom and side surfaces of a groove 192 formed in a third interlayer insulating film 165 are provided with a storage electrode 166 and a capacitor insulating film 167 (in concave shapes). The bottom surface of the storage electrode 166 is electrically connected to a corresponding one of doped source and drain layers 154 of a DRAM cell transistor through a storage node contact 164, a contact pad 161 formed in the same layer as a bit line 162, and a contact plug 159. In the step shown in FIG. 6A, a TiN film (not shown) is deposited over the entire capacitor insulating film 167, and the deposited film is patterned using a photoresist 171 to form a plate electrode 175 in a DRAM region 190 and a dummy plate 176 in a logic region 191.

Next, in the step shown in FIG. 6B, a plate contact hole 195 passing through the plate electrode 175 is formed in the DRAM region 190, while a contact hole 194 passing through the third and second interlayer insulating films 165 and 163 and reaching the contact pad 161 is formed in an area of the logic region 191 provided with no dummy plate 176. Subsequently, the surfaces of the plate contact hole 195 and the contact hole 194 are covered with a barrier film 196 and then the resulting holes are filled with TiN, thereby forming a plate contact plug 180 and a logic contact plug 179. Metal wires 182 are then formed on the plate contact plug 180 and the logic contact plug 179, respectively.

In the above-described conventional method for fabricating a DRAM-embedded semiconductor device, the dummy plate electrode 176 is formed in the logic region 191. Therefore, a level difference resulting from the thickness of the plate electrode 175 is not created between the DRAM region 190 and the logic region 191. Furthermore, in the logic portion 191, a wide opening as shown in FIGS. 4A, 4B, and 5 does not have to be formed and only an opening for forming the logic contact plug 179 has to be formed. The diameter of the opening may be a value of the diameter of the logic contact plug 179 plus a margin, and for each opening, this diameter can be set almost uniformly. Therefore, the microloading effect during etching thereof hardly arises. This prevents ununiform etching and reduces the amount of overetching for the opening in the logic region 191. Thus, deep etching of the third interlayer insulating film 165 in the logic region 191 can be reduced, which makes it difficult to create a level difference between the DRAM region 190 and the logic region 191.

In the conventional method for fabricating a DRAM-embedded semiconductor device shown in FIGS. 6A and 6B, however, parasitic capacitance produced by the dummy plate electrode 176 becomes a big problem. In particular, it is seriously detrimental to a request for ultra high-speed operation of a DRAM as a substitute memory for a SRAM, so that in this case, formation of the dummy plate electrode 176 in the logic region 191 is extremely difficult.

Further, if the plate electrode 175 and the dummy plate electrode 176 are thinned in order to decrease the aspect ratio of the logic contact plug 179, the plate contact 180 penetrates the plate electrode 125. Thus, the plate contact 180 is virtually brought into contact only with the side surface of the plate electrode 175. In this case, a problem of an unstable contact of the plate contact 180 with the plate electrode 175 arises.

### SUMMARY OF THE INVENTION

With the foregoing in mind, an object of the present invention is to provide a semiconductor device which can prevent the occurrence of a level difference of an interlayer insulating film between a DRAM region and a logic region without involving an increase in parasitic capacitance or other troubles and which can control the depth of a plate contact more accurately, and to provide a method for fabricating such a device.

A semiconductor device of the present invention comprises a capacitor including: a storage electrode; a capacitor insulating film provided on the storage electrode; and a plate electrode which is provided on the capacitor insulating film and which has a first conductive film and a second conductive film disposed on the first conductive film and differing from the first conductive film in etching rate.

In a fabrication process of the semiconductor device having such a structure, a plate electrode can be formed as follows: after a first conductive film and a second conductive film are formed over the entire upper surface of a substrate, etching is performed on the second and first conductive films in this order on the condition that the second conductive film has a higher etching rate than the first conductive film, so that the second conductive film can be patterned using the first conductive film as a stopper and then the remaining first conductive film can be removed. In the conventional technique, when etching for forming the plate electrode is performed, overetching due to a microloading effect occurs in a region in which no capacitor is provided. This creates a level difference at the boundary between the region provided with a capacitor and the region provided with no capacitor. On the other hand, in the present invention, the first conductive film acts as a stopper also in the region provided with no capacitor, so that a layer located below the first conductive film is not removed. Therefore, creation of the level difference can be prevented. Thus, even though a photoresist is applied to the substrate after completion of the formation of the plate electrode, shift of focus resulting from the level difference does not occur. This also prevents resolution failure and therefore enables a more accurate control of the depth and width of the opening and prevention of occurrence of opening failure. Consequently, the fabrication yield of the device can be improved.

Moreover, unlike the technique disclosed in Prior Art Document 2, in the semiconductor device of the present invention, no plate electrode remains in the region provided with no capacitor. Therefore, a trouble such that a parasitic capacitance is produced does not arise.

The storage electrode, the capacitor insulating film, and the plate electrode may constitute a capacitor of a DRAM, and the capacitor may be provided below a bit line.

Preferably, the first conductive film contains oxygen. Thus, the first conductive film and the second conductive film can have greatly different etching rates.

Preferably, the first conductive film is a TiN film containing oxygen. In this case, the first conductive film can be formed by repeating a cycle that consists of formation of the TiN film at a low temperature of 400° C. or lower and then annealing with NH₃ supplied at the same temperature as the temperature of that formation. This results from the fact that low crystallinity of the TiN film formed at low temperatures causes an easy diffusion of oxygen in the film.

Preferably, the concentration of oxygen in the first conductive film is from 5 atm % to 30 atm % both inclusive.

The semiconductor device of the present invention may further comprise a first interlayer insulating film, and the storage electrode may cover side and bottom surfaces of a groove formed in the first interlayer insulating film.

A second interlayer insulating film may be provided on the plate electrode, and the device may further comprise: a contact plug passing through the second interlayer insulating film to come into contact with an upper surface or an inside of the plate electrode; and a wiring material provided on the second interlayer insulating film to electrically connect to the contact plug. In the process steps of forming such a structure, when the contact hole is formed which passes through the second interlayer insulating film to reach the plate electrode, etching for this formation can be performed using the first conductive film as a stopper. Therefore, full penetration of the contact hole through the plate electrode can be prevented. Consequently, a more reliable electrical connection between the contact plug and the plate electrode can be ensured.

A method for fabricating a semiconductor device according to the present invention is characterized by comprising: the step (a) of forming a storage electrode which covers side and bottom surfaces of a groove formed in part of a first interlayer insulating film; the step (b) of forming a capacitor insulating film at least on the storage electrode; the step (c) of forming a first conductive film on a region which extends from the top of a portion of the capacitor insulating film located in the groove to the top of a portion of the first interlayer insulating film located outside the groove; the step (d) of forming a second conductive film on the first conductive film; the step (e) of performing, using the first conductive film as a stopper, etching with a first type of gas to remove a portion of the second conductive film located outside the groove; and the step (f) of performing etching with a second type of gas to remove a portion of the first conductive film located outside the groove.

This eliminates the possibility of removing the first interlayer insulating film below the first conductive film in the step (e), which prevents the occurrence of a level difference at the boundary between the region provided with a capacitor and the region provided with no capacitor, which would conventionally be found. Thus, even though a photoresist is applied to the substrate after completion of the step (e), shift of focus resulting from the level difference does not occur. This also prevents resolution failure and therefore enables a more accurate control of the depth and width of the opening and prevention of occurrence of opening failure.

Moreover, unlike the technique disclosed in Prior Art Document 2, in the method for fabricating a semiconductor device according to the present invention, portions of the first and second conductive films located in the region provided with no capacitor are removed in the steps (e) and (f). Therefore, a semiconductor device of low parasitic capacitance can be formed.

Preferably, the first type of gas includes chlorine gas, and the second type of gas includes bromine chloride and chlorine. In this case, if the first conductive film is a TiN film containing oxygen and the second conductive film is a TiN film, the second film can be removed selectively in the step (e) and concurrently the first film can be removed reliably in the step (f).

The steps (e) and (f) may be carried out to form, in the groove, a plate electrode having the first conductive film and the second conductive film, and the method may further comprise: the step (g) of forming, after the step (f), a second interlayer insulating film covering the top of the plate electrode and the top of the first interlayer insulating film; and the step (h) of performing, after the step (g), etching using the first conductive film as a stopper to form a contact hole passing through the second interlayer insulating film and reaching an upper surface or an inside of the plate electrode. In this case, the contact hole does not penetrate the first conductive film in the step (g), so that a semiconductor device having a reliable connection between the contact plug and the plate electrode can be formed.

### BRIEF DESCRIPTION OF THE DRAWINGS

FIGS. 1A and 1B are sectional views showing fabrication steps of a DRAM-embedded semiconductor device according to a first embodiment of the present invention.

FIGS. 2A and 2B are sectional views showing fabrication steps of the DRAM-embedded semiconductor device according to the first embodiment of the present invention.

FIG. 3 is a graph showing the result obtained by measuring, by Auger spectroscopy, the composition of a TiN film formed at a low temperature of 400° C. or lower.

FIGS. 4A and 4B are sectional views showing conventional fabrication steps of a DRAM-embedded semiconductor device with a CUB structure in which a bit line is formed in a layer present on a storage capacitor.

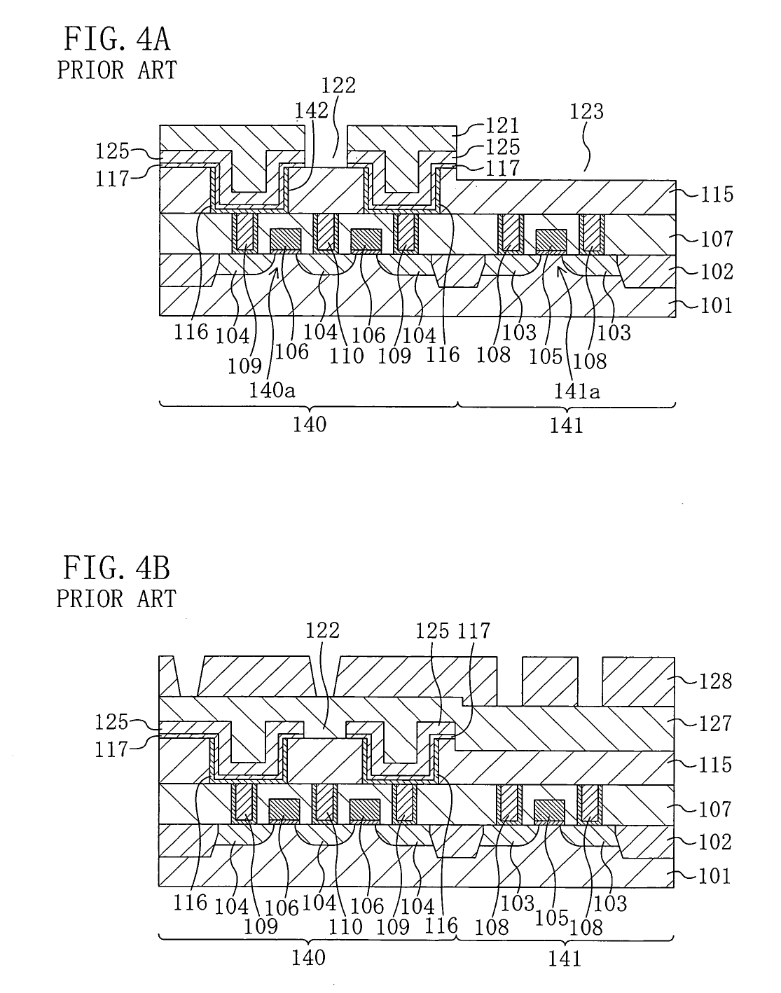

FIG. 5 is a sectional view showing a conventional fabrication step of the DRAM-embedded semiconductor device with the CUB structure in which the bit line is formed in the layer present on the storage capacitor.

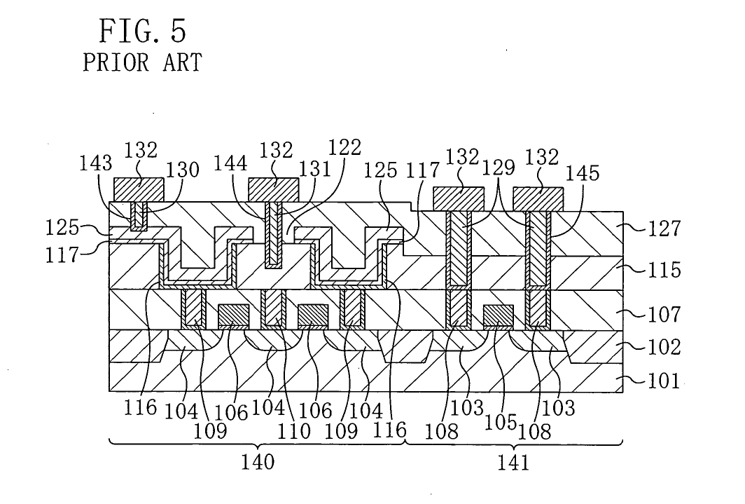

FIGS. 6A and 6B are sectional views showing conventional fabrication steps of a DRAM-embedded semiconductor device with a COB structure in which a storage capacitor is formed in a layer present on a bit line.

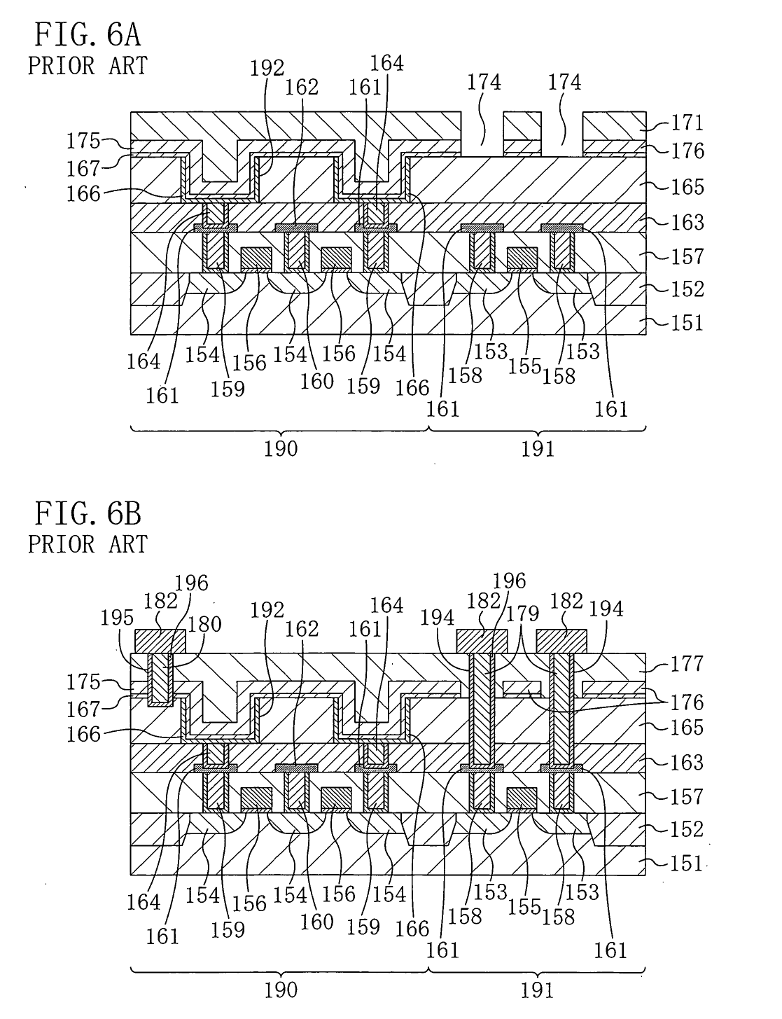

### DETAILED DESCRIPTION OF THE PREFERRED EMBODIMENTS

### First Embodiment

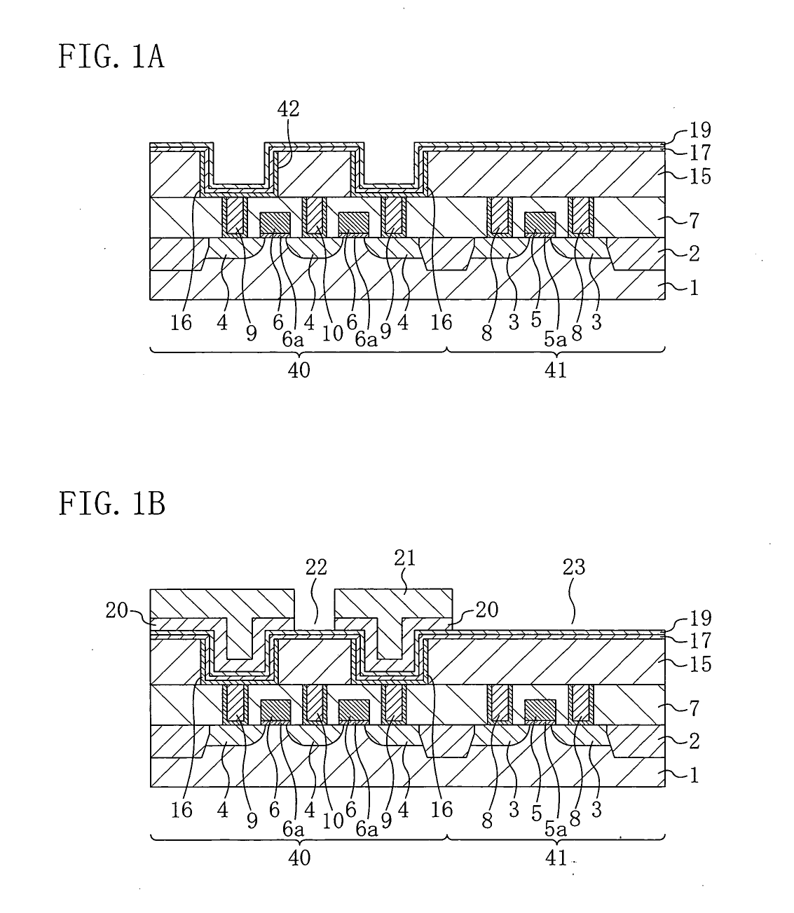

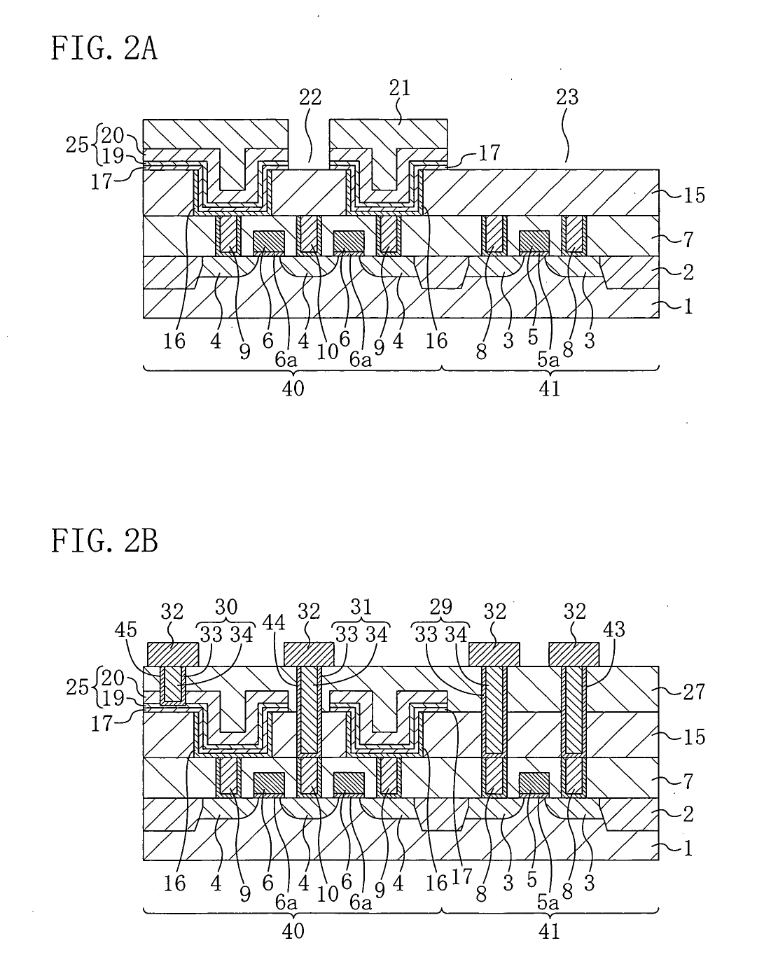

FIGS. 1A, 1B, 2A, and 2B are sectional views showing fabrication steps of a DRAM-embedded semiconductor device according to a first embodiment of the present invention.

In the fabrication method of the first embodiment, first, in the step shown in FIG. 1A, an isolation region (STI) 2 is formed in a p-type semiconductor substrate 1. Areas of the p-type semiconductor substrate 1 surrounded with the isolation region 2 are formed with doped source and drain layers 3 and 4, respectively. Above a portion of the p-type semiconductor substrate 1 located in a DRAM region 40, a gate electrode 6 is formed with a gate insulating film 6a interposed therebetween, thereby forming a DRAM memory cell transistor. Above a portion of the p-type semiconductor substrate 1 located in a logic region 41, a gate electrode 5 is formed with a gate insulating film 5a interposed therebetween, thereby forming a logic transistor. Thereafter, a first interlayer insulating film 7 covering the gate electrodes 5 and 6 is deposited over the p-type semiconductor substrate 1, and then a logic contact plug 8 and a storage contact plug 9 are formed. The logic contact plug 8 passes through the first interlayer insulating film 7 to reach a corresponding one of the doped source and drain layers 3 in the logic transistor. The storage contact plug 9 passes through the first interlayer insulating film 7 to reach a corresponding one of the doped source and drain layers 4 in the DRAM memory cell transistor.

A second interlayer insulating film 15 is then deposited on the first interlayer insulating film 7, and the second interlayer insulating film 15 is formed with a 500 nm-deep groove 42 reaching the storage contact plug 9. Subsequently, by a CVD method, a 20 nm-thick TiN film is deposited to cover bottom and side surfaces of the groove 42, and the deposited film is etched back to form a storage electrode (lower electrode) 16. A 10 nm-thick capacitor insulating film 17 of tantalum oxide is deposited on the storage electrode 16, and then a 20 nm-thick TiOₓN_{y} film 19 is formed on the capacitor insulating film 17. A concrete formation method of the TiOₓN_{y} film 19 is as follows. A CVD method is conducted with TiCl₄ and NH₃ supplied at 400° C. or lower to form a thin film of TiN having a thickness of about 2 nm, and then annealing is performed with NH₃ supplied at the same processing temperature as the temperature of the CVD method. Thereafter, the CVD method and the annealing with NH₃ are repeated to form a TiN film having a thickness of about 5 to 20 nm. Since a TiN film formed at low temperatures has low crystallinity, oxygen diffuses easily in the film to form the TiOₓN_{y}film 19. Note that it is more preferable that the formation temperature of the TiN film is from 340 to 350° C. inclusive. Further, by repeating deposition of the thin film, abnormal growth of the deposited film can be suppressed. However, of course, the TiOₓN_{y} film 19 may be formed so that without repeating deposition of the thin film, a CVD method is conducted only once to form the TiN film and that oxygen is introduced into the formed film by utilizing annealing.

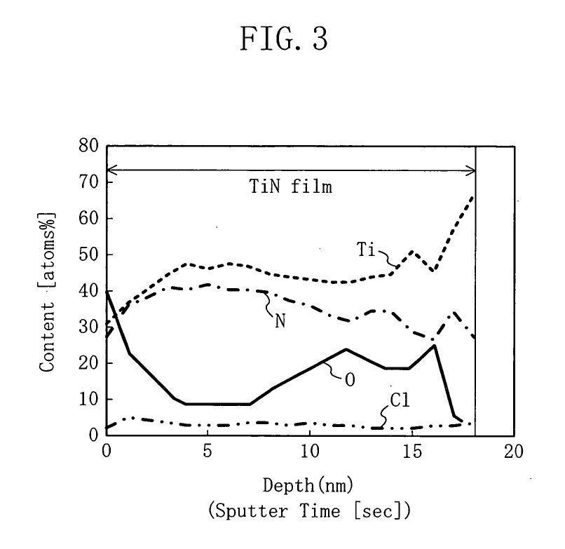

FIG. 3 is a graph showing the result obtained by measuring, by Auger spectroscopy, the composition of the TiN film formed at a low temperature of 400° C. or lower. FIG. 3 plots the depth of the measurement in abscissa and the percentage of each component in the film in ordinate. As shown in FIG. 3, it is found that oxygen enters the TiN film at a ratio of about 10 to 20% of the total composition.

Next, in the step shown in FIG. 1B, on the TiOₓN_{y} film 19, a 30 nm-thick TiN film 20 is deposited by a sputtering method. Then, a photoresist 21 is deposited on the TiN film 20, and dry etching with chlorine gas is performed to form, in the TiN film 20, a 200 nm-diameter opening 22 for forming a bit line contact and a wide opening 23 located in the logic region. By the dry etching with chlorine gas, the TiN film 20 formed by a sputtering method is etched at an etching rate of 80 nm/min, while the TiOₓN_{y} film 19 is etched at an etching rate of 8 nm/min, which is about one-tenth of the etching rate of the TiN film 20. Therefore, the TiOₓN_{y} film 19 is hardly etched.

Subsequently, in the step shown in FIG. 2A, etching with bromine chloride/chlorine gas is performed using the photoresist 21 as a mask to pattern the TiOₓN_{y} film 19 and the capacitor insulating film 17. Thereby, a plate electrode 25 is formed which is made of the TiN film 20 and the TiOₓN_{y} film 19. The etching rate of the TiOₓN_{y} film 19 by this etching is about 40 nm/min.

In the step shown in FIG. 2B, a third interlayer insulating film 27 is deposited on the second interlayer insulating film 15 and the plate electrode 25, and then a logic contact hole 43, a plate contact hole 45, and a bit line contact hole 44 are formed. The logic contact hole 43 and the bit line contact hole 44 have to be formed to pass through the third and second interlayer insulating films 27 and 15 and then reach the logic contact plug 8 and a bit-line contact plug 10, respectively, while the plate contact hole 45 has only to be formed to reach the plate electrode 25. Thus, the plate contact hole 45 is likely to be formed deeper than a desired depth. However, if this etching is performed using a mixed gas of C₅F₈/O₂/Ar, etching of the plate contact hole 45 can be stopped within the TiOₓN_{y} film 19. This is because the etching with this mixed gas can etch an oxide film at an etching rate of 500 nm/min, the TiN film 20 formed by sputtering at an etching rate of 50 nm/min, and the TiOₓN_{y} film 19 at an etching rate of 5 nm/min, so that the TiN film 20 and the TiOₓN_{y} film 19 are more difficult to remove than the third and second interlayer insulating films 27 and 15.

Next, the surfaces of the respective contact holes 43 to 45 are covered with a CVD-TiN film 33, and then the resulting contact holes are filled with a metal film 34 of W or the like to form a logic contact plug 29 and a bit-line contact plug 31 which have a depth of 700 nm, and a plate contact plug 30 having a depth of 150 nm. Then, metal wires 32 are formed which are electrically connected to the contact plugs 29 to 31, respectively.

With the first embodiment, when the TiN film 20 of the plate electrode 25 is processed in the step shown in FIG. 1B, the underlying TiOₓN_{y} film 19 can be used as an etching stopper to suppress overetching of the wide opening 23. Therefore, even though the third interlayer insulating film 27 is formed on the plate electrode 25 and the second interlayer insulating film 15 in the step shown in FIG. 2B, it becomes difficult to create a level difference on the top of the third interlayer insulating film 27. Thus, even though a photoresist is applied onto the third interlayer insulating film 27, shift of focus resulting from the level difference does not occur. This also prevents resolution failure and therefore enables a more accurate control of the depth and width of the opening. To be more specific, a trouble such that shallowing of the opening as compared with a desired depth causes opening failure can be prevented.

Moreover, with the first embodiment, when the plate contact hole 45 is formed in the step shown in FIG. 2B, etching for this formation can be performed using the TiOₓN_{y} film 19 as an etching stopper. This eliminates the possibility of removing the plate contact hole 45 deeper than a desired value, so that the phenomenon in which the plate contact hole 45 penetrates the plate electrode 25 and then only the side surface of the plate contact plug 30 comes into contact with the plate electrode 25 hardly arises. Typically, on the surface of the contact hole, the TiN film 33 formed by CVD is used as an adhesion layer. If the TiN film is formed by CVD, TiCl₄ is likely to be formed. Since TiCl₄ has a high resistance, an ammonia plasma treatment as a post treatment has to be performed in order to reduce its resistance value. However, even though the ammonia plasma treatment is performed, it is difficult for this treatment to completely reach the side surface of the contact hole. As a result, the resistance of the side surface thereof still remains high. Thus, when the side surface of the plate contact plug 30 comes into contact with the plate electrode 25, the resistance produced by this contact is high. However, the first embodiment can avoid such a trouble. As a concrete resistance value, in the conventional technique, the resistance of the 120 nm-diameter contact is 500 Ω, while in the first embodiment, contact of the plate electrode 25 with the bottom surface of the plate contact plug 30 can reduce its resistance to about 200 Ω.

What is claimed is:

1. A semiconductor device which comprises a capacitor including:
a storage electrode;
a capacitor insulating film provided on the storage electrode; and
a plate electrode which is provided on the capacitor insulating film and which has a first conductive film and a second conductive film disposed on the first conductive film and differing from the first conductive film in etching rate.

2. The device of claim 1,
wherein the storage electrode, the capacitor insulating film, and the plate electrode constitute a capacitor of a DRAM, and
the capacitor is provided below a bit line.

3. The device of claim 1,
wherein the first conductive film contains oxygen.

4. The device of claim 3,
wherein the first conductive film is a TiN film containing oxygen.

5. The device of claim 4,
wherein the concentration of oxygen in the first conductive film is from 5 atm % to 30 atm % both inclusive.

6. The device of claim 1, further comprising a first interlayer insulating film,
wherein the storage electrode covers side and bottom surfaces of a groove formed in the first interlayer insulating film.

7. The device of claim 6,
wherein a second interlayer insulating film is provided on the plate electrode, and the device further comprises:
a contact plug passing through the second interlayer insulating film to come into contact with an upper surface or an inside of the plate electrode; and
a wiring material provided on the second interlayer insulating film to electrically connect to the contact plug.

8. A method for fabricating a semiconductor device, comprising:
the step (a) of forming a storage electrode which covers side and bottom surfaces of a groove formed in part of a first interlayer insulating film;
the step (b) of forming a capacitor insulating film at least on the storage electrode;
the step (c) of forming a first conductive film on a region which extends from the top of a portion of the capacitor insulating film located in the groove to the top of a portion of the first interlayer insulating film located outside the groove;
the step (d) of forming a second conductive film on the first conductive film;
the step (e) of performing, using the first conductive film as a stopper, etching with a first type of gas to remove a portion of the second conductive film located outside the groove; and
the step (f) of performing etching with a second type of gas to remove a portion of the first conductive film located outside the groove.

9. The method of claim 8,
wherein the first type of gas includes chlorine gas, and
the second type of gas includes bromine chloride and chlorine.
10. The method of claim 8,
wherein the steps (e) and (f) are carried out to form, in the groove, a plate electrode having the first conductive film and the second conductive film, and
the method further comprises:
the step (g) of forming, after the step (f), a second interlayer insulating film covering the top of the plate electrode and the top of the first interlayer insulating film; and
the step (h) of performing, after the step (g), etching using the first conductive film as a stopper to form a contact hole passing through the second interlayer insulating film and reaching an upper surface or an inside of the plate electrode.
